(19) United States
(12) Patent Application Publication
(10) Pub. No.: US 2010/0212588 A1
(43) Pub. Date: Aug. 26, 2010

(54) SEMICONDUCTOR SINGLE CRYSTAL PRODUCTION APPARATUS

(75) Inventors: Ayumi Suda, Nagasaki (JP); Naoji Mitani, Nagasaki (JP)

Correspondence Address: KRATZ, QUINTOS & HANSON, LLP, 1420 K Street, N.W., 4th Floor, WASHINGTON, DC, 20005, US

(73) Assignee: SUMCO TECHXIV CORPORATION, Omura-shi (JP)

(21) Appl. No.: 12/671,091

(22) PCT Filed: Jul. 2, 2008
(86) PCT No.: PCT/JP2008/061976

§ 371 Date: Jan. 28, 2010

(30) Foreign Application Priority Data
Aug. 2, 2007 (JP) 2007-202014

(51) Int. Cl. H01L 21/365

(52) U.S. Cl. 118/663; 257/E21.463

(57) ABSTRACT

An apparatus designed to increase the quality of a low-resistance semiconductor single crystal doped with an N-type volatile dopant to a high concentration and increase the production yield by controlling the pressure inside the furnace with good controllability. A vacuum line, a pressure control valve, and an open valve are newly added to the conventional semiconductor single crystal production apparatus. A controller controls the pressure control valve on the basis of a detection value of pressure detection means so as to obtain the desired low resistance value of the semiconductor single crystal. The open valve is controlled so that the open valve is opened in a case where the pressure inside the furnace detected by the pressure detection means reaches an abnormal value.

### TECHNICAL FIELD

The present invention relates to a semiconductor single crystal production apparatus, and more particularly to an apparatus in which an inert gas is supplied in a furnace and a semiconductor single crystal doped with a dopant is produced inside the furnace, while discharging the gas in the furnace from an outlet (discharge) via a vacuum line.

### BACKGROUND ART

### Conventional Technology

A demand was created in recent years for high-yield production of silicon wafers for use in discrete semiconductor devices and the like, namely, low-resistance silicon wafers that have N-type electric characteristics and are doped to a high concentration with a volatile dopant.

Examples of N-type volatile dopants referred to herein include antimony Sb, red phosphorus P, and arsenic As. The low resistance is a resistance value equal to or lower than 20/1000 Ωcm.

FIG. 1 shows a configuration of a conventional silicon single crystal production apparatus 1. This conventional apparatus 1 is constructed to produce silicon wafers that have a concentration lower and a resistance higher than those of the above-described high-concentration and low-resistance silicon wafer, for example, a silicon wafer with a resistance value equal to or higher than 1 Ωcm.

In the conventional apparatus 1, an inert gas is supplied in an CZ furnace 2 and a silicon single crystal ingot doped with a dopant is produced in the CZ furnace 2, while discharging the gas in the furnace from outlets (discharge) 4, 5 via a normal vacuum line 10.

In the CZ furnace 2, a silicon single crystal ingot doped with a dopant is pulled from the melt and grown by a CZ (Czochralski) method.

A high vacuum is maintained in the furnace 2 by cutting off the inside of the CZ furnace 2 from the external atmosphere. Thus, argon gas is supplied as an inert gas into the CZ furnace 2 and discharged from the outlets (discharge) 4, 5 of the CZ furnace 2 by a vacuum pump 8. As a result, the pressure inside the furnace 2 is reduced to the predetermined level.

A variety of evaporants are generated in the CZ furnace 2 in the single crystal pulling process (1 batch).

The inside of the CZ furnace 2 is then evacuated by the vacuum pump 8, and the gas inside the CZ furnace 2 is discharged together with the evaporants via the normal vacuum line 10. As a result, evaporants are removed from inside the CZ furnace 2. A normal pressure control valve 11 is provided in the normal vacuum line 10. With the normal pressure control valve 11, the pressure inside the CZ furnace 2 is regulated within a pressure range corresponding to the normal vacuum region (referred to hereinbelow as “normal furnace pressure region”), namely, within a range of 0.1 to 13.3 kPa. A silicon single crystal ingot is thus pulled and grown, while maintaining the pressure inside the CZ furnace 2 at a desired level within the normal furnace pressure region, thereby producing a low-concentration and high-resistance silicon single crystal ingot (appropriately referred to hereinbelow as “normal furnace pressure product”).

Therefore, when a low-resistance silicon single crystal ingot doped to a high concentration with an N-type volatile dopant is to be produced by using the above-described conventional apparatus 1, the pressure inside the CZ furnace 2 has to be regulated by using the normal pressure control valve 11 suitable for control in the above-described normal furnace pressure region.

### (Conventional Technology Described in Patent Documents)

Patent Document 1 describes an invention according to which carbon concentration in a crystal is controlled by regulating a pressure inside a furnace when a compound semiconductor single crystal is pulled and grown by a liquid encapsulated Czochralski (LEC) method.

Patent Document 2 describes an invention according to which oxygen concentration on a melt surface is controlled by regulating a pressure of atmosphere that is in contact with the melt when a silicon single crystal is pulled and grown by a CZ method.

Patent Document 3 describes an invention according to which a flow velocity in the vicinity of a melt surface of an inert gas flowing between a gas guide inside a CZ furnace and the melt is controlled by regulating the pressure inside the CZ furnace when a silicon single crystal is pulled and grown by a CZ method.

Patent Document 1: Japanese Patent Application Laid-open No. H9-221390.

Patent Document 2: Japanese Patent Application Laid-open No. H7-232990.

Patent Document 3: Japanese Patent Application Laid-open No. H5-70279

The inventors, using the conventional apparatus 1, made an attempt to produce a low-resistance silicon single crystal ingot doped to a high concentration with a volatile dopant and encountered the following problems that led to the creation of the present invention.

Thus, in order to produce a low-resistance silicon single crystal ingot doped to a high concentration with a volatile dopant in the CZ furnace 2, it is necessary to inhibit the evaporation of the dopant from the melt because of dopant volatility.

Where the pressure inside the CZ furnace 2 is not raised, active evaporation proceeds from the melt in the pulling process, a large amount of gas containing the dopant is discharged and the resistance value of the silicon single crystal ingot deviates and becomes higher than the desired value.

Accordingly, it is necessary to use the conventional normal pressure control valve 11 and regulate the pressure inside the CZ furnace 2 to a pressure range of 13.3 to 93.3 kPa (referred to hereinbelow as “sub-vacuum region”) that is higher than the normal furnace pressure region, thereby inhibiting the evaporation of volatile dopants and maintaining the dopant concentration in the silicon single crystal ingot at a high concentration level.

However, the normal pressure control valve 11 is basically a pressure control valve suitable for control within the normal furnace pressure region (0.1 to 13.3 kPa) and is configured so as to perform regulation with good controllability in the normal furnace pressure region. For this reason, when the normal pressure control valve 11 is used for regulation in the sub-vacuum region (13.3 to 93.3 kPa) in which the vacuum degree is lower and the pressure is higher than those in the normal furnace pressure region, the controllability drops significantly. Therefore, pressure fluctuations inside the CZ furnace 2 increase, the amount of dopant evaporated from the melt fluctuates, and the resistance value or oxygen concentration in the silicon single crystal ingot vary significantly. As a result, the resistance value of the silicon single crystal ingot cannot be stabilized at the desired low resistance value, quality of the low-resistance silicon single crystal ingot doped to a high concentration with an N-type volatile dopant (referred to hereinbelow appropriately as “high furnace pressure product”) can decrease, and the production yield can decrease.

### DISCLOSURE OF THE INVENTION

The present invention is created with the foregoing in view, and a first problem to be resolved by the present invention is to increase the quality of a low-resistance semiconductor single crystal doped to a high concentration with an N-type volatile dopant and increase the production yield of the single crystal by controlling the pressure inside the furnace with good controllability.

In the production of a low-resistance silicon single crystal ingot (high furnace pressure product) doped to a high concentration with a volatile dopant in the CZ furnace 2, an important point is that the dopant evaporated from the melt due to the dopant volatility forms an amorphous compound and flows in a large amount into the vacuum line 10.

Where the inflow of a large amount of amorphous compound containing the dopant to the vacuum line 10 is allowed to continue for a long time, the amorphous compound adheres to the piping inner surface of the vacuum line 10 and the adhered substance accumulates and can eventually clog the piping. The adhesion of amorphous compound to the piping is specific to the high furnace pressure product, and the phenomenon of adhesion to the piping is not observed when a normal furnace pressure product is produced.

Where the exhaust line 10 is clogged by the amorphous compound or the pressure control valve 11 is damaged, the gas inside the CZ furnace 2 cannot be discharged to the vacuum pump 8 side, and the pressure inside the CZ furnace 2 rises abnormally. Thus, because the pressure in the sub-vacuum region is from the beginning higher than that in the normal furnace pressure region, the pressure inside the furnace rapidly rises to an abnormal pressure.

Where the pressure inside the CZ furnace 2 rises abnormally, the high-pressure gas in the CZ furnace 2 can flow out to the outside. Therefore, in order to prevent such a gas outflow, care can be taken to stop the supply of inert gas entering the CZ furnace 2.

However, such a method can inhibit the rise in pressure inside the CZ furnace 2, but cannot decrease the pressure inside the furnace.

Thus, where the supply of argon gas into the CZ furnace 2 is stopped after the pressure inside the CZ furnace 2 has risen to an abnormal pressure exceeding the upper limit of 93.3 kPa of the sub-vacuum region, the inert gas enclosed in the furnace is heated in accordance with the remaining amount of the inert gas inside the CZ furnace 2. In this case, since no gas flows inside the CZ furnace 2, no heat exchange by gas is performed inside the furnace, and the enclosed inert gas rises the temperature even in portions that are normally not heated. Such temperature increase in various zones inside the furnace can fracture seal members of various types, such as O-rings, in the furnace chamber. As a result, an external air penetrates into the furnace chamber from the portions of the furnace chamber with poor sealing ability and raises pressure inside the furnace. The gas contained in the furnace is thus caused to flow out of the furnace.

Because this gas flowing out of the furnace has a high temperature, this gas can burn the operator. Furthermore, because the amorphous compound contained in the gas includes a toxic dopant, namely arsenic As, antimony Sb, and the like, it can adversely affect the operator's health. Moreover, the outflow of the amorphous compound from the furnace contaminates the clean room and inevitably degrades the product quality and decreases the production yield.

The present invention was created with the foregoing in view and a second problem to be resolved by the present invention is to avoid the adverse effect produced on the operator, avoid the contamination of the clean room, improve the product quality, and increase the production yield by preventing the gas from flowing out of the furnace when producing a low-resistance semiconductor single crystal doped to a high concentration with an N-type volatile dopant.

As described hereinabove, the conventional silicon single crystal production apparatus 1 constructed with the object of producing the normal furnace product is not necessarily suitable for producing the high furnace pressure product. However, where a novel silicon single crystal production apparatus suitable for producing the high furnace pressure product is separately constructed, the equipment cost may increase and it may be unable to dispose the apparatus in a limited installation space.

Accordingly, a third problem to be resolved by the present invention is to enable the construction of an apparatus suitable for producing both the normal furnace pressure product and the high furnace pressure product by only slight modification of the conventional silicon single crystal production apparatus 1, to control the equipment cost, and to enable the disposition of the apparatus in a limited space, without adding a new furnace.

The object of regulating the pressure inside the furnace that is described in the aforementioned patent documents is to regulate the concentration of carbon in the crystal, or control the concentration of oxygen on the melt surface, or control the flow velocity of inert gas. None of these objects suggests any of the problems to be resolved by the present invention.

The first invention of the present invention relates to:

a semiconductor single crystal production apparatus in which an inert gas is supplied in a furnace and a semiconductor single crystal doped with a dopant is produced inside the furnace, while discharging the gas in the furnace from an outlet (discharge) via a vacuum line, including:

when a low-resistance semiconductor single crystal doped with a volatile dopant to a high concentration is produced in the furnace,

a high furnace pressure vacuum line and an emergency vacuum line that are provided independently from each other and parallel to each other, are linked to the outlet (discharge), and discharge the gas in the furnace;

a pressure control valve that is provided in the high furnace pressure vacuum line, regulates a pressure inside the furnace within a pressure range corresponding to a sub-vacuum region for inhibiting evaporation of a volatile dopant and obtaining a high dopant concentration in the semiconductor single crystal;

an open valve provided in the emergency vacuum line;

pressure detection means for detecting the pressure inside the furnace;

first control means for controlling the pressure control valve on the basis of a detected value of the pressure detection means so as to obtain a desired low resistance value of the semiconductor single crystal; and

second control means for controlling the open valve so as to open the open valve in a case where the pressure inside the furnace detected by the pressure detection means reaches an abnormal value.

The second invention of the present invention relates to:

a semiconductor single crystal production apparatus in which an inert gas is supplied in a furnace and a semiconductor single crystal doped with a dopant is produced inside the furnace, while discharging the gas in the furnace from an outlet (discharge) via a vacuum line, and

in which a low-resistance semiconductor single crystal doped with a volatile dopant to a high concentration and a semiconductor single crystal with a resistance higher than that of the low-resistance product are produced in the furnace, the semiconductor single crystal production apparatus comprising:

a high furnace pressure vacuum line and a normal vacuum line that are provided independently from each other and parallel to each other, are linked to the outlet (discharge), and discharge the gas in the furnace;

a normal pressure control valve that is provided in the normal furnace pressure vacuum line and regulates a pressure inside the furnace within a high-vacuum range;

a high pressure control valve that is provided in the high furnace pressure vacuum line, has an aperture size set smaller than that of the normal pressure control valve, and regulates the pressure inside the furnace within a low-vacuum range; and

control means for controlling the high pressure control valve when the low-resistance semiconductor single crystal is produced and controlling the normal pressure control valve when the high-resistance semiconductor single crystal is produced.

The third invention of the present invention relates to

a semiconductor single crystal production apparatus in which an inert gas is supplied in a furnace and a semiconductor single crystal doped with a dopant is produced inside the furnace, while discharging the gas in the furnace from an outlet (discharge) via a vacuum line, and

in which a low-resistance semiconductor single crystal doped with a volatile dopant to a high concentration and a semiconductor single crystal with a resistance higher than that of the low-resistance product are produced in the furnace, the semiconductor single crystal production apparatus comprising:

a high furnace pressure vacuum line, a normal vacuum line, and an emergency vacuum line that are provided independently from each other and parallel to each other, are linked to the outlet (discharge), and discharge the gas in the furnace;

a normal pressure control valve that is provided in the normal furnace pressure vacuum line and regulates a pressure inside the furnace within a high-vacuum range;

a high pressure control valve that is provided in the high furnace pressure vacuum line, has an aperture size set smaller than that of the normal pressure control valve, and regulates the pressure inside the furnace within a low-vacuum range;

an open valve provided in the emergency vacuum line;

pressure detection means for detecting the pressure inside the furnace;

first control means for controlling the high pressure control valve when the low-resistance semiconductor single crystal is produced and controlling the normal pressure control valve when the high-resistance semiconductor single crystal is produced; and

second control means for controlling the open valve so as to open the open valve in a case where the pressure inside the furnace detected by the pressure detection means reaches an abnormal value.

According to the first invention, as shown in FIG. 2, a semiconductor single crystal production apparatus 1 is provided with a high furnace pressure vacuum line 20, a high pressure control valve 21, pressure detection means 50, and first control means 40.

The high furnace pressure vacuum line 20 discharges the gas in a furnace 2 from the outlets (discharge) 4, 5 to a safe external site via the vacuum pump 8.

The high pressure control valve 21 is provided in the high furnace pressure vacuum line 20. The high pressure control valve 21 regulates the pressure inside the furnace 2 within a pressure range corresponding to the sub-vacuum region for inhibiting evaporation of a volatile dopant and obtaining a semiconductor single crystal with a high dopant concentration.

The pressure detection means 50 detects the pressure P inside the furnace 2.

The controller 40 controls the high pressure control valve 21 on the basis of the detected value P of the pressure detection means 50 so as to obtain the semiconductor single crystal with the desired low resistance value (FIG. 3, steps 101 to 107).

In accordance with the first invention, the high pressure control valve 21 is configured so that the pressure can be regulated with good controllability in the sub-vacuum region. Therefore, the controllability of pressure inside the furnace in the sub-vacuum region is greatly improved over that of the conventional pressure control valve 11 shown in FIG. 1. As a result, the resistance value of the semiconductor single crystal can be stabilized at the desired low resistance value, quality of the low-resistance semiconductor single crystal doped to a high concentration with an N-type volatile dopant, which is a high furnace pressure product, can be increased, and the production yield is raised.

Furthermore, according to the first invention, an emergency vacuum line 30, an open valve 31, and a second control means 40 are further provided.

The emergency vacuum line 30 is provided independently of the high furnace pressure vacuum line 20 and parallel thereto and linked to the outlets (discharge) 4, 5. This vacuum line discharges the gas inside the furnace 2.

The open valve 31 is provided in the emergency vacuum line 30.

The second control means 40 controls the open valve 31 so that the open valve 31 is opened in a case where the pressure P inside the furnace that is detected by the pressure detection means 50 reaches an abnormal value P2 (FIG. 4, steps 201 to 206). As a result, even when a large amount of an amorphous compound that includes a dopant flows into the high furnace pressure vacuum line 20 and the high furnace pressure vacuum line 20 is clogged due to adhesion and accumulation of the amorphous compound or the high pressure control valve 21 is damaged, whereby the pressure inside the furnace 2 rises abnormally, the open valve 31 is opened and the gas in the furnace 2 is discharged from the outlets (discharge) 4, 5 by the vacuum pump 8 to an external safe site through the emergency vacuum line 30 provided independently of the high furnace pressure vacuum line 20.

Therefore, according to the first invention, when a low-resistance semiconductor single crystal doped to a high concentration with an N-type volatile dopant is produced, the outflow of gas to the outside of the furnace 2 can be reliably prevented, the adverse effect produced on the operator can be avoided, contamination of the clean room can be avoided, and product quality and production yield can be improved.

The first invention may also include a configuration in which another vacuum line 10 is provided in addition to the high furnace pressure vacuum line 20 and emergency vacuum line 30 as shown in FIG. 2 and a configuration in which only the high furnace pressure vacuum line 20 and emergency vacuum line 30 are provided as shown in FIG. 6.

In accordance with the second invention, the apparatus can be constructed by newly adding the vacuum line 20 and pressure control valve 21 to the conventional semiconductor single crystal apparatus 1 (FIG. 1) and changing the contents of processing performed in the conventional control means 40. Thus, an apparatus suitable for producing both the normal furnace pressure product and the high furnace pressure product can be easily constructed by slightly changing the conventional semiconductor single crystal apparatus 1 (FIG. 1), namely, by newly adding the vacuum line 20 and pressure control valve 21. As a result, the equipment cost can be controlled and the apparatus can be disposed in a limited installation space, without adding an additional furnace. In this case, a high-resistance semiconductor single crystal (normal furnace pressure product) is produced by controlling the normal pressure control valve 11 provided in the normal vacuum line 10 with the control means 40 and regulating the pressure inside the furnace 2, in the same manner as in the conventional semiconductor single crystal apparatus 1 shown in FIG. 1. For the normal furnace pressure product, the pulling conditions such as oxygen concentration are set in the normal furnace pressure region. Therefore, the normal furnace product of high quality can be produced with good yield under pulling conditions that are the same as the conventional pulling conditions.

The second invention also may include a configuration in which another vacuum line 30 is provided in addition to the high furnace pressure vacuum line 20 and normal vacuum line 10 as shown in FIG. 2 and a configuration in which only the high furnace pressure vacuum line 20 and normal vacuum line 10 are provided as shown in FIG. 7.

In accordance with the third invention, the emergency vacuum line 30, open valve 31, and second control means 40 are provided in addition to the configuration in accordance with the second invention.

The effect obtained with the third invention is similar to that of the second invention.

Furthermore, in accordance with the third invention, similarly to the first invention, the open valve 31 is controlled (FIG. 4, steps 201 to 206) so that the open valve 31 is opened in a case where the pressure P inside the furnace that is detected by the pressure detection means 50 reaches an abnormal value P2. Therefore, even if the pressure inside the furnace 2 increases abnormally, the open valve 31 is opened and the gas inside the furnace 2 is discharged from the outlets (discharge) 4, 5 via the vacuum pump 8 to a safe external site through the emergency vacuum line 30 provided independently of the high furnace pressure vacuum line 20 and normal vacuum line 10.

Therefore, in accordance with the third invention, the outflow of gas to the outside of the furnace 2 can be reliably prevented, the adverse effect produced on the operator can be avoided, contamination of the clean room can be avoided, and product quality and production yield can be improved.

### BRIEF DESCRIPTION OF THE DRAWINGS

FIG. 1 illustrates the configuration of the conventional silicon single crystal production apparatus.

FIG. 2 illustrates the configuration of the silicon single crystal production apparatus of the first embodiment.

FIG. 3 is a flowchart showing the control processing procedure of a normal pressure control valve and high pressure control valve; this figure illustrates the contents of processing performed in the controller.

FIG. 4 is a flowchart showing the control processing procedure of an open valve; this figure illustrates the contents of processing performed in the controller.

FIG. 5 illustrates the configuration of the silicon single crystal production apparatus of the second embodiment.

FIG. 6 illustrates the configuration of the silicon single crystal production apparatus of the third embodiment.

FIG. 7 illustrates the configuration of the silicon single crystal production apparatus of the fourth embodiment.

FIG. 8 illustrates schematically the flow of an inert gas from a CZ furnace to a vacuum pump.

FIG. 9 shows a correspondence relationship in which a valve angle is plotted against the abscissa and an opening area is plotted against the ordinate.

FIG. 10 shows the relationship between the valve angle and opening area.

FIG. 11 shows a correspondence relationship in which a pressure is plotted against the abscissa and a valve angle is plotted against the ordinate.

### BEST MODE FOR CARRYING OUT THE INVENTION

Embodiments of the apparatus for producing a semiconductor single crystal in accordance with the present invention will be described below with reference to the drawings.

### First Embodiment

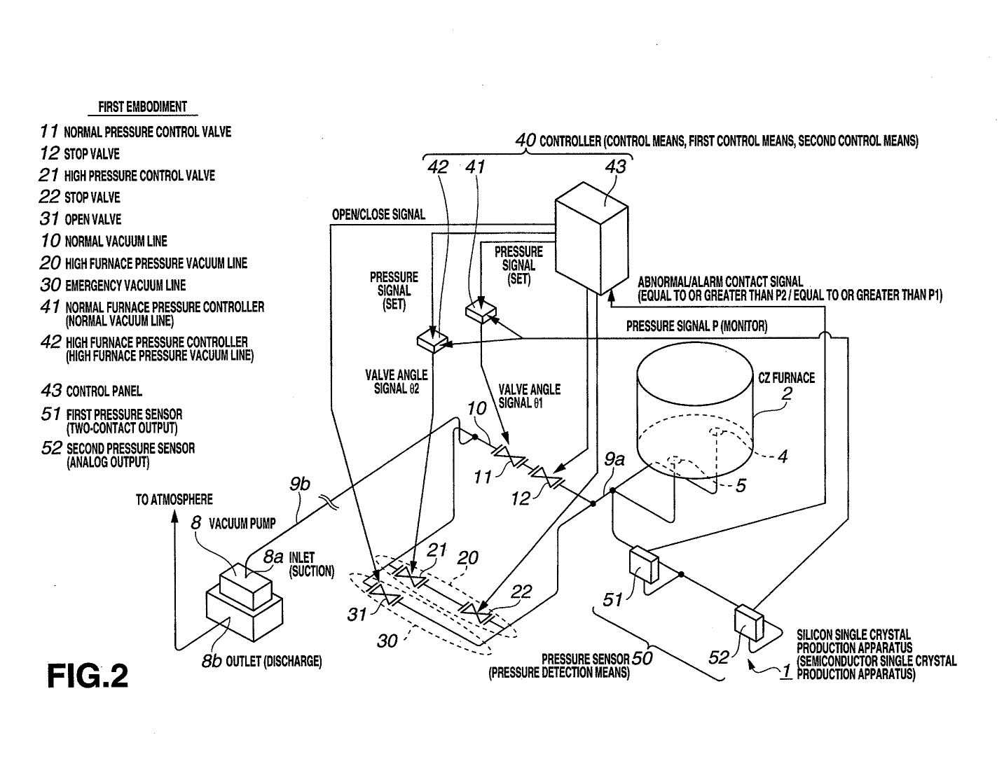

FIG. 2 shows the configuration of a silicon single crystal production apparatus 1 of the embodiment. The apparatus 1 of this embodiment serves to produce a volatile N-type high-concentration and low-resistance silicon wafer (high furnace pressure product) and a silicon wafer (normal furnace pressure product) with a concentration lower and a resistance higher than those of the high furnace pressure product. The silicon single crystal production apparatus 1 is installed in a clean room.

The “N-type volatile dopant” as referred to herein is antimony Sb, red phosphorus P, and arsenic As, etc. The “low resistance” is taken as a resistance value that is equal to or lower than 20/1000 Ωcm.

Outlets (discharge) 4, 5 of a CZ furnace 2 are provided on the lower side of the CZ furnace 2. In the present embodiment, a structure is assumed in which gas is discharged from the lower side of the CZ furnace 2, but gas outlets (discharge) may be provided in any location of the CZ furnace 2.

The outlets (discharge) 4, 5 of the CZ furnace 2 are linked to a common vacuum line 9a.

A normal vacuum line 10, a high furnace pressure vacuum line 20, and an emergency vacuum line 30 are provided in parallel independently from each other and linked to the outlets (discharge) 4, 5 of the CZ furnace 2 via the common vacuum line 9a.

A common vacuum line 9b is linked to the normal vacuum line 10, high furnace pressure vacuum line 20, and emergency vacuum line 30. An intake port 8a of a vacuum pump 8 is linked to the common vacuum line 9b. An outlet (discharge) 8b of the vacuum pump 8 is linked to a safe site (atmosphere) outside the clean room. The vacuum pump 8 is shared by the normal vacuum line 10, high furnace pressure vacuum line 20, and emergency vacuum line 30, but it is also obviously possible to provide individual vacuum pumps for the normal vacuum line 10, high furnace pressure vacuum line 20, and emergency vacuum line 30.

The normal vacuum line 10, high furnace pressure vacuum line 20, and emergency vacuum line 30 thus feed the gas that was in the CZ furnace 2 and discharged from the outlets (discharge) 4, 5 to the vacuum pump 8 for discharge to a safe external site.

In the silicon single crystal production apparatus 1 of the present embodiment, an inert gas such as argon gas is supplied in the CZ furnace 2 and a silicon single crystal ingot doped with a dopant is produced inside the CZ furnace 2, while discharging the gas in the CZ furnace from the outlets (discharge) 4, 5 via the normal vacuum line 10 and high furnace pressure vacuum line 20.

Inside the CZ furnace 2, the silicon single crystal ingot is pulled up from a melt and grown by a CZ (Czochralski) method.

High vacuum is maintained inside the furnace 2 by cutting off the external atmosphere from the CZ furnace 2. Thus, argon gas is supplied as an inert gas into the CZ furnace 2, and the CZ furnace 2 is evacuated with the vacuum pump 8 from the outlets (discharge) 4, 5. As a result, the pressure inside the CZ furnace 2 is reduced to a predetermined level.

Various evaporants are generated inside the CZ furnace 2 during a single crystal pulling process (1 batch).

Accordingly, the inside of the CZ furnace 2 is evacuated by the vacuum pump 8 and gas contained inside the CZ furnace 2 is discharged together with the evaporants via the normal vacuum line 10 and high furnace pressure vacuum line 20. As a result, the evaporants are removed from inside the CZ furnace 2.

A normal pressure control valve 11 and a stop valve 12 are provided in the normal vacuum line 10. The normal pressure control valve 11 is configured by a throttle valve having a butterfly valve. The stop valve 12 is configured by an air-driven ball valve.

The normal pressure control valve 11 is configured to regulate the pressure inside the CZ furnace 2 to a pressure range corresponding to a normal furnace pressure region, namely, 0.1 to 13.3 kPa.

The normal pressure control valve 11 is controlled by a controller 40 serving as a control means.

The stop valve 12 is manually controlled by an operator.

In the high furnace pressure vacuum line 20, a high pressure control valve 21 that regulates the pressure inside the CZ furnace 2 within a low-vacuum range is provided, the aperture size of the high pressure control valve 21 is set smaller than that in the normal pressure control valve 11.

A stop valve 22 is provided in the high furnace pressure vacuum line 20. The high pressure control valve 21 is configured by a throttle valve having a butterfly valve. The stop valve 22 is configured by an air-driven ball valve.

The high pressure control valve 21 is configured to regulate the pressure inside the CZ furnace 2 within a pressure range corresponding to a sub-vacuum region.

The sub-vacuum region as referred to herein is a pressure range for inhibiting the evaporation of volatile dopants and increasing the dopant concentration in the silicon single crystal ingot. This is pressure range of 13.3 to 93.3 kPa in which the pressure is higher than in the normal furnace pressure region.

The high pressure control valve 21 is controlled by the controller 40.

The stop valve 22 is manually controlled by the operator.

An open valve 31 is provided in the emergency vacuum line 30. The open valve 31 is constituted by an air-driven stop valve. The open valve 31 is controlled by the controller 40.

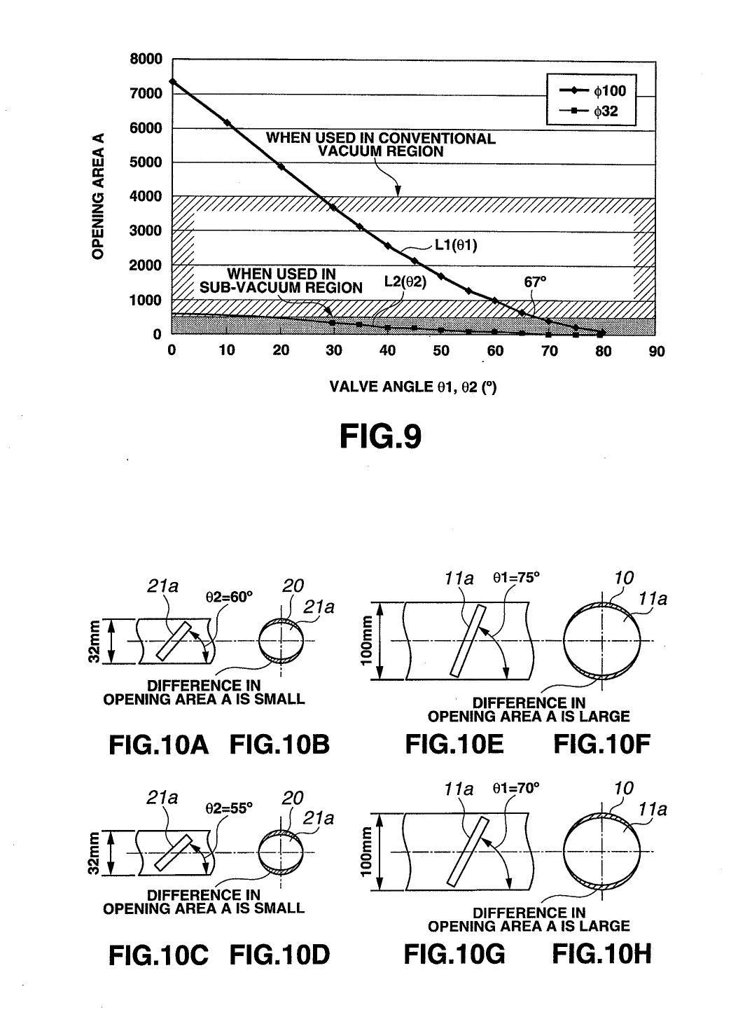

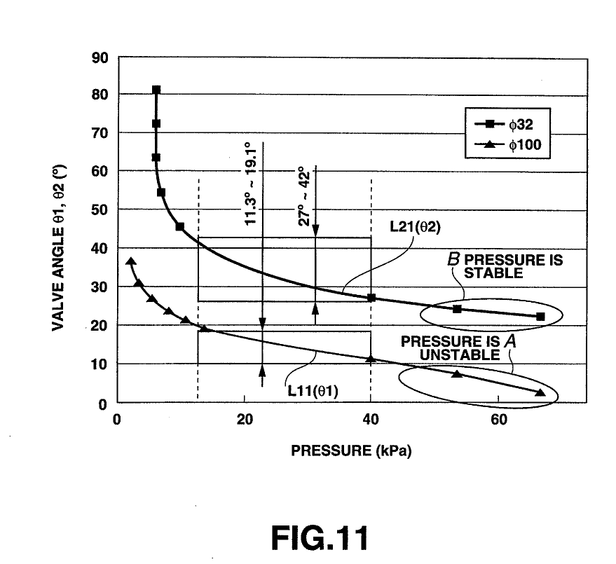

The normal pressure control valve 11 and high pressure control valve 21 will be explained below with reference to FIG. 8, FIG. 9, FIG. 10, and FIG. 11.

FIG. 8 shows schematically a flow of inert gas from the CZ furnace 2 to the vacuum pump 8.

Where a flow rate of gas flowing through one piping 10 or 20 is denoted by Q, a pressure upstream of the pressure control valve 11 or 21, that is, a pressure inside the CZ furnace 2, is denoted by P, and a pressure downstream of the pressure control valve 11 or 21 is denoted by PB, the gas flow rate Q can be represented by the following Equation (1):

Q=C·(P−PB) (1)

C in Equation (1) is a conductance of the pressure control valve 11 or 21, which is an inverse of resistance. The conductance C is essentially determined by the channel shape and opening area A in the pressure control valve 11 or 21. Because the channel shape is practically fixed, the conductance C of the pressure control valve 11 or 21 is generally changed by changing the opening area A. As follows from Equation (1), the pressure (pressure inside the CZ furnace 2) P upstream of the pressure control valve 11 or 21 can be controlled by regulating the conductance C of the pressure control valve 11 or 21.

Therefore, the pressure (pressure inside the CZ furnace 2) P upstream of the pressure control valve 11 or 21 can be controlled by changing the opening area A of the pressure control valve 11 or 21 and regulating the conductance C of the pressure control valve 11 or 21.

Because the conductance C is an inverse of resistance, where the opening area A becomes small, the conductance C becomes small, and where the opening area A becomes large, the conductance C becomes large.

Therefore, in a region in which the pressure (pressure inside the CZ furnace 2) P upstream of the pressure control valve 11 or 21 is comparatively low, controllability improves if the opening area A is large. Conversely, in a region in which the pressure (pressure inside the CZ furnace 2) P upstream of the pressure control valve 11 or 21 is comparatively high, controllability improves if the opening area A is small.

Based on the above-described principle, the aperture size (maximum value of opening area A) of the normal pressure control valve 11 is set comparatively large and the regulation is performed in a region with a large opening area A, thereby improving controllability in a low-pressure (high-vacuum) region (normal furnace pressure region). At the same time, the aperture size (maximum value of opening area A) of the high pressure control valve 21 is set comparatively small and regulation is performed in a region with a small opening area A, thereby improving controllability in a high-pressure (low-vacuum) region (sub-vacuum region).

Specific numerical values are presented below to explain the pressure control valves 11, 21, but the numerical values presented in the description merely serve, as examples, to explain the invention, and the present invention is not limited to the numerical values presented in the description.

FIG. 9 and FIG. 10 are used for the explanation based on comparison of controllability attained when the inner diameter of a piping of the high furnace pressure vacuum line 20 is 32 mm and the pressure range corresponding to a sub-vacuum region is regulated by an angle (referred to hereinbelow as a valve angle θ2) of a butterfly valve 21a of the high pressure control valve 21 and controllability attained when the inner diameter of a piping of the normal vacuum line 10 is 100 mm and the pressure range corresponding to the same sub-vacuum region is regulated by an angle (referred to hereinbelow as a valve angle θ1) of a butterfly valve 11a of the normal pressure control valve 11.

FIG. 9 shows correspondence relationships L1, L2 in which the valve angles θ1, θ2 (°) are plotted against the abscissa, and the opening area A (mm²) is plotted against the ordinate. As shown in FIG. 9, the aperture size of the pressure control valves 11, 21 is taken to correspond to the inner diameter of the piping 10, 20 respectively.

In the present embodiment, a structure is assumed in which the pressure control valves 11, 21 are constituted by respective throttle valves, and the valve angles θ1, θ2 of butterfly valves 11a, 21a are changed to regulate the opening area A and thereby change the conductance C. However, the structure of the pressure control valves 11, 21 is not limited to a throttle valve, and pressure control valves of any structure can be applied to the present invention, provided that the conductance C can be changed.

As follows from FIG. 9, when the pressure range corresponding to the sub-vacuum region is controlled, the valve angles θ1, θ2 have to be regulated within a range of opening area A of from 0 to 700 mm². By contrast, when the pressure range corresponding to the normal furnace pressure region is controlled, the valve angles θ1, θ2 have to be regulated within a range of opening area A of from 700 mm² to 4000 mm².

With the high pressure control valve 21, the range of from 0 to 700 mm² of the opening area A corresponding to the sub-vacuum region can be regulated by changing the valve angle θ2 within a wide angular range of from 0° to 80°, as shown in L2. By contrast, with the normal pressure control valve 11, the range of from 0 to 700 mm² of the opening area A corresponding to the sub-vacuum region can be regulated by changing the valve angle θ1 within a narrow angular range of from 67° to 80°, as shown in L1.

With the normal pressure control valve 11, the range of from 700 mm² to 4000 mm² of the opening area A corresponding to the normal furnace pressure region can be regulated by changing the valve angle θ1, but with the high pressure control valve 21, the range of from 700 mm² to 4000 mm² of the opening area A corresponding to the normal furnace pressure region cannot be regulated by changing the valve angle θ2.

FIG. 10 shows the relationship between valve angles θ1, θ2 and opening area A.

As shown in FIG. 10(a), (b), (c), and (d), with the high pressure control valve 21, when the valve angle θ2 changes from 55° to 60°, that is, by 5°, the opening area A changes from 122.8 mm² to 90.9 mm², that is, by 31.9 mm², and the difference in the opening area A is comparatively small. By contrast, as shown in FIG. 9(e), (f), (g), and (h), with the normal pressure control valve 11, when the valve angle θ1 changes from 70° to 75°, that is, by 5°, the opening area A changes from 450.2 mm² to 254.3 mm², that is, by 195.9 mm², and the difference in the opening area A is comparatively large. Thus, the variation amount of the opening area A per unit valve angle (5°) in the sub-vacuum region (opening area A: 0 to 700 mm²) is much smaller in the high pressure control valve 21 than in the normal pressure control valve 11.

As described hereinabove, it is clear that in the sub-vacuum region in which the pressure is controlled within a range of the opening area A of 0 to 700 mm², pressure controllability of the high pressure control valve 21, which has a small aperture size of the valve, is better than that of the normal pressure control valve 11.

FIG. 11 shows correspondence relationships L11, L21 in which the pressure P (kPa) is plotted against the abscissa and valve angles θ1, θ2 (°) are plotted against the ordinate. These experimental data were obtained by passing an inert gas at a flow rate of 100 l/min inside the CZ furnace 2.

In FIG. 11, the variation amounts of valve angles θ1, θ2 are compared in a pressure range of 13.3 to 40.0 kPa within the sub-vacuum region. The range of 13.3 to 40.0 kPa was selected as a range in which pressure can be controlled with good stability with both the normal pressure control valve 11 and the high pressure control valve 21.

As shown in L11 in FIG. 11, when controlling the same pressure range of 13.3 to 40.0 kPa in the sub-vacuum region, with the normal pressure control valve 11, the valve angle θ1 changes from 11.3° to 19.1°, that is, merely by 7.8°, whereas, as shown in L21, with the high pressure control valve 21, the control can be performed with a variation amount that is about twice as large valve angle θ2 changes from 27° to 42°, that is, by 15°. The comparison conducted for the same pressure range also demonstrates that pressure controllability of the high pressure control valve 21, which has a small aperture size of the valve, is substantially better than that of the normal pressure control valve 11.

Furthermore, as shown in A in the same FIG. 11, on the high-pressure side of the sub-vacuum region, the variations of pressure P against the variations of valve angle θ1 become unstable with the normal pressure control valve 11, but as shown in B, the variations of pressure P follow the variations of valve angle θ2 with good stability with the high pressure control valve 21. Therefore, where controllability on the high-pressure side of the sub-vacuum region is considered, the high pressure control valve 21, which has a small aperture size of the valve, is also greatly superior in terms of pressure control stability to the normal pressure control valve 11.

In the explanation above, the aperture size of pressure control valves 11, 21 is assumed to correspond to the inner diameter of piping 10, 20, respectively, as shown in FIG. 10, but in another possible configuration the inner diameters of piping 10, 20 are the same and only the aperture sizes of the pressure control valves 11, 21 are different.

A configuration of the controller 40 that controls the normal pressure control valve 11 and high pressure control valve 21 will be explained below.

As shown in FIG. 2, the controller 40 includes a control panel 43, a normal furnace pressure controller 41, and a high furnace pressure controller 42.

A pressure sensor 50 that indirectly detects the pressure P inside the CZ furnace 2 by detecting the pressure of gas flowing in the common vacuum line 9a is provided in the vacuum line 9a. The pressure sensor 50 includes a first pressure sensor 51 and a second pressure sensor 52. The first pressure sensor 51 is configured by a pressure switch with a two-contact output. In the first pressure sensor 51, pressures P1, P2 (P1<P2) are set as contact output values (threshold values). Where the detected pressure P reaches the threshold value P1, an alarm contact signal is outputted, and where the pressure P reaches the threshold value P2, an abnormal contact signal is outputted.

The second pressure sensor 52 is constituted by an analog sensor and serves to detect the present furnace pressure value P in the CZ furnace 2 and output as a pressure monitor value.

An abnormal/alarm contact signal outputted from the first pressure sensor 51 is inputted in the control panel 43. A pressure signal P (monitor) outputted from the second pressure sensor is inputted as a feedback value in the normal furnace pressure controller 41 and high furnace pressure controller 42.

The control panel 43 is provided, as described hereinbelow, with a switch that instructs the production under normal furnace pressure conditions or high furnace pressure conditions.

Where a normal furnace pressure condition for producing the normal furnace pressure product is instructed by the switch, the control panel 43 generates a pressure signal (SET) corresponding to the normal furnace pressure condition and outputs the signal to the normal furnace pressure controller 41. The pressure signal (SET) corresponds to a target pressure value Pr1 within the normal furnace pressure region. The normal furnace pressure controller 41 computes a valve angle θ1 for reducing the difference between the target pressure value Pr1 and the pressure signal P (monitor) to zero and outputs as a valve angle signal to the normal pressure control valve 11. As a result, the butterfly valve 11a of the normal pressure control valve 11 is actuated and the valve angle θ1 changes to the commanded angle.

Likewise, where a high furnace pressure condition for producing the high furnace pressure product is instructed by the switch, the control panel 43 generates a pressure signal (SET) corresponding to the high furnace pressure condition and outputs the signal to the high furnace pressure controller 42. The pressure signal (SET) corresponds to a target pressure value Pr2 within the sub-vacuum region. The high furnace pressure controller 42 computes a valve angle θ2 for reducing the difference between the target pressure value Pr2 and the pressure signal P (monitor) to zero and outputs as a valve angle signal to the high pressure control valve 21. As a result, the butterfly valve 21a of the high pressure control valve 21 is actuated and the valve angle θ2 changes to the commanded angle.

Where an abnormal contact signal is inputted, the control panel 43 generates an open signal for opening the open valve 31 and outputs the generated signal to the open valve 31. As a result, the open valve 31 is opened by the air-driven actuator and the emergency vacuum line 30 is opened. In a normal state, a close signal is outputted (open signal OFF) from the control panel 43, the open valve 31 is closed, and the emergency vacuum line 30 is closed.

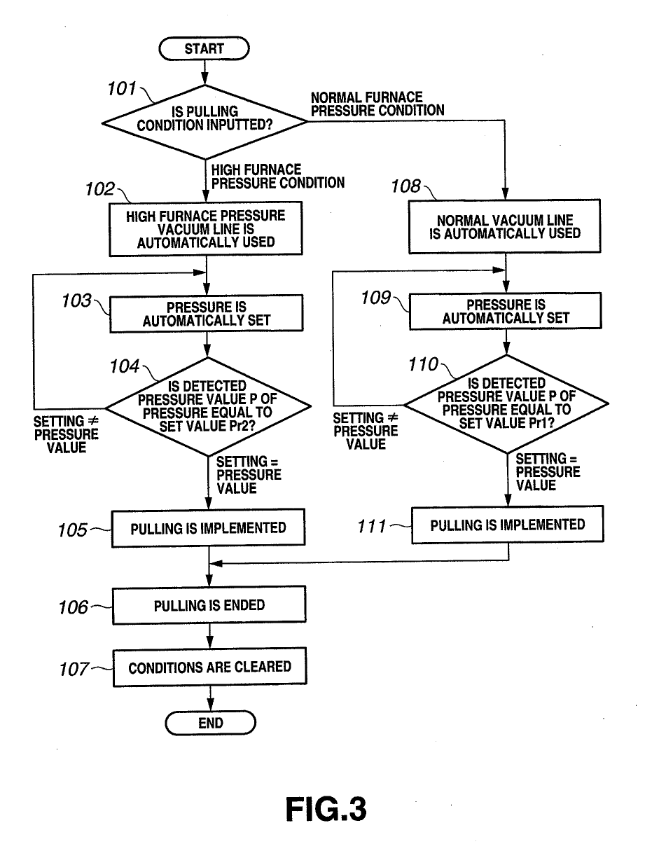

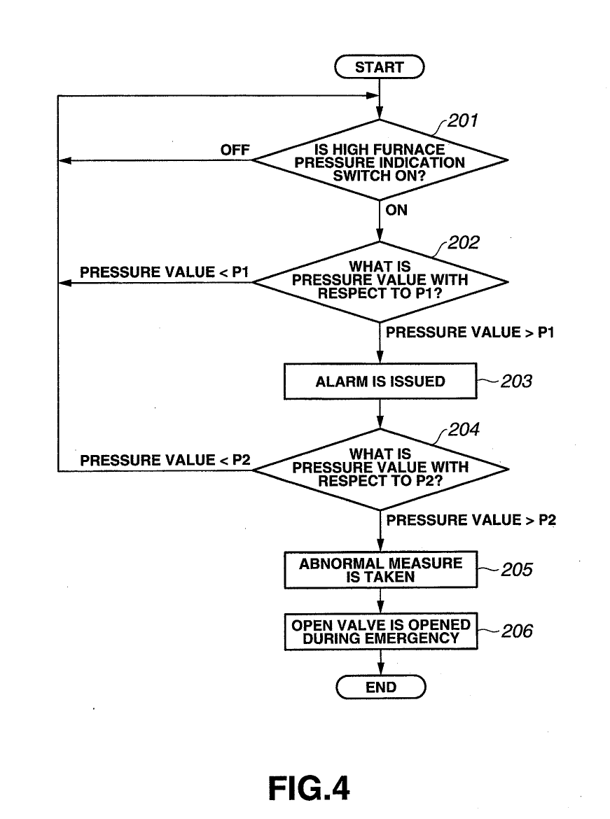

The contents of processing performed by the controller 40 will be explained below with reference to the flowcharts shown in FIG. 3 and FIG. 4.

FIG. 3 is a flowchart illustrating the control processing procedure of the normal pressure control valve 11 and high pressure control valve 21.

If the operator operates the switch of the control panel 43 and instructs and inputs a normal furnace pressure condition for producing a normal furnace pressure product as a pulling condition (step 101), then a pressure signal (SET) is outputted to the normal furnace pressure controller 41 and high furnace pressure controller 42 in order to set the normal pressure control valve 11 in an open state and set the high pressure control valve 21 in a closed state so as to use the normal vacuum line 10. As a result, the butterfly valve 11a of the normal pressure control valve 11 is actuated and the normal pressure control valve 11 assumes an open state. The butterfly valve 21a of the high pressure control valve 21 is also actuated and the high pressure control valve 21 assumes a closed state (step 108).

Then, a pressure signal (SET) indicating the target pressure value Pr1 corresponding to the normal furnace pressure condition is generated and outputted to the normal furnace pressure controller 41. The normal furnace pressure controller 41 computes a valve angle θ1 for reducing the difference between the target pressure value Pr1 and the pressure signal P (monitor) detected by the second pressure sensor 52 to zero and outputs as a valve angle signal to the normal pressure control valve 11. As a result, the butterfly valve 11a of the normal pressure control valve 11 is actuated and the valve angle θ1 changes to the commanded angle (steps 109, 110).

If the pressure signal P (monitor) detected by the second pressure sensor 52 reaches the target pressure value Pr1, pulling of the silicon single crystal ingot is started (step 111). As a result, a low-concentration and high-resistance silicon single crystal ingot is pulled under the normal furnace pressure condition, while the pressure inside the CZ furnace 2 is controlled to a desired value within the normal furnace pressure region. Once the pulling under the normal furnace pressure condition ends (step 106), the instruction of the pulling condition is cleared (step 107) and the processing returns to the initial step 101 as a preparation for the next batch.

If the operator operates the switch of the control panel 43 and instructs and inputs a high furnace pressure condition for producing a high furnace pressure product as a pulling condition (step 101), then a pressure signal (SET) is outputted to the normal furnace pressure controller 41 and high furnace pressure controller 42 in order to set the high pressure control valve 21 in an open state and set the normal pressure control valve 11 in a closed state so as to use the high furnace pressure vacuum line 20. As a result, the butterfly valve 11a of the normal pressure control valve 11 is actuated and the normal pressure control valve 11 assumes a closed state. The butterfly valve 21a of the high pressure control valve 21 is also actuated and the high pressure control valve 21 assumes an opened state. When the pressure control is performed with the high furnace pressure vacuum line 20, the normal vacuum line 10 may be closed. Furthermore, by controlling a conductance to be sufficiently less than the conductance of the high pressure control valve 21, without increasing excessively the opening degree of the normal vacuum line 10, pressure controllability in the sub-vacuum region can be improved (step 102).

Then, a pressure signal (SET) indicating the target pressure value Pr2 corresponding to the high furnace pressure condition is generated and outputted to the high furnace pressure controller 42. The high furnace pressure controller 42 computes a valve angle θ2 for reducing the difference between the target pressure value Pr2 and the pressure signal P (monitor) detected by the second pressure sensor 52 to zero and outputs as a valve angle signal to the high pressure control valve 21. As a result, the butterfly valve 21a of the high pressure control valve 21 is actuated and the valve angle θ2 changes to the commanded angle (steps 103, 104).

If the pressure signal P (monitor) detected by the second pressure sensor 52 reaches the target pressure value Pr2, pulling of the silicon single crystal ingot is started (step 105). As a result, a volatile N-type high-concentration and low-resistance silicon single crystal ingot is pulled under the high furnace pressure condition, while the pressure inside the CZ furnace 2 is controlled to a desired value within the sub-vacuum region. Once the pulling under the high furnace pressure condition ends (step 106), the instruction of the pulling condition is cleared (step 107) and the processing returns to the initial step 101 as a preparation for the next batch.

The flowchart shown in FIG. 3 is explained under an assumption that either of the pressure control in a sub-vacuum region or pressure control in the normal furnace pressure region is conducted, but pressure control is not conducted in a pressure region including the region bridging the sub-vacuum region and normal furnace pressure region in one-batch one-pulling process. However, a silicon single crystal ingot can be also pulled in a pressure region including the region bridging the sub-vacuum region and normal furnace pressure region. In such a case, processing is performed in which the normal pressure control valve 11 and high pressure control valve 21 are controlled simultaneously by using a control formula such as PID control.

FIG. 4 is a flowchart illustrating a control processing procedure for the open valve 31. The processing illustrated by FIG. 4 is performed in parallel with that illustrated by FIG. 3.

If the operator operates the switch of the control panel 43 and instructs and inputs a high furnace pressure condition for producing a high furnace pressure product as a pulling condition (step 201), then an alarm/abnormal processing of step 202 and subsequent steps is performed. This is because the sub-vacuum region in which the high furnace pressure product is originally produced has a pressure higher than that of the normal furnace pressure region and, therefore, the pressure inside the CZ furnace 2 can rapidly rise to an abnormal pressure.

In step 202, it is determined whether an alarm contact signal has been outputted from the first pressure sensor 51 (step 202).

In a case where the detection pressure P has reached the threshold value P1 and the alarm contact signal has been outputted, an alarm generation means such as a buzzer or a warning light (not shown in the figure) is actuated and an alarm is produced for the operator. The threshold value P1 is set, for example, to 84.0 kPa (step 203).

Then, it is determined whether an abnormal contact signal has been outputted from the first pressure sensor 51 (step 204)

Where the detected pressure P has reached the threshold value P2 and an abnormal contact signal has been outputted, an abnormal processing is performed. An open signal for opening the open valve 31 is generated and outputted to the open valve 31. As a result, the open valve 31 is opened by an air-driven actuator and an emergency vacuum line 30 is opened. At the same time, a pressure control that controls the pressure in the CZ furnace 2 to a target pressure value is stopped. The threshold value P2 is set to, for example, 90.7 kPa (steps 205, 206).

The explanation relating to FIG. 4 was given under an assumption that the alarm/abnormal processing of step 202 and subsequent steps is conducted when a high furnace pressure condition for producing a high furnace pressure product is instructed as a pulling condition, but the alarm/abnormal processing of step 202 and subsequent steps may be also conducted in a similar manner when the normal furnace pressure condition for producing a normal furnace pressure product is instructed.

The effect of the first embodiment will be explained below.

(Effect A) According to the first embodiment, the high pressure control valve 21 that can regulate the pressure with good controllability in the sub-vacuum region is provided in the high furnace pressure vacuum line 20, and the high pressure control valve 21 is controlled by the controller 40 (steps 101 to 107 in FIG. 3). Therefore, the evaporation of the dopant is inhibited and control to the desired dopant concentration can be conducted with good accuracy. As a result, quality of the low-resistance silicon single crystal doped with an N-type volatile dopant to a high concentration, which is a high furnace pressure product, can be increased and the production yield of such crystal is increased.

(Effect B) Furthermore, according to the first embodiment, in a case where the pressure P inside the CZ furnace that is detected by the pressure sensor 51 reaches the abnormal pressure P2, the controller 40 controls the open valve 31 so as to open the open valve 31 (steps 201 to 206 in FIG. 4). Therefore, even when a large amount of an amorphous compound that includes a dopant flows into the high furnace pressure vacuum line 20 and the high furnace pressure vacuum line 20 is clogged due to adhesion and accumulation of the amorphous compound or when the high pressure control valve 21 is damaged thereby and the pressure inside the CZ furnace 2 rises abnormally, the open valve 31 is opened and the gas in the CZ furnace 2 is discharged from the outlets (discharge) 4, 5 via the vacuum pump 8 to an external safe site through the emergency vacuum line 30 provided independently of the high furnace pressure vacuum line 20.

Therefore, in accordance with the first embodiment, when a low-resistance silicon single crystal doped to a high concentration with an N-type volatile dopant is produced, the outflow of gas to the outside of the CZ furnace 2 can be reliably prevented, the adverse effect produced on the operator can be avoided, contamination of the clean room can be avoided, and product quality and production yield can be improved.

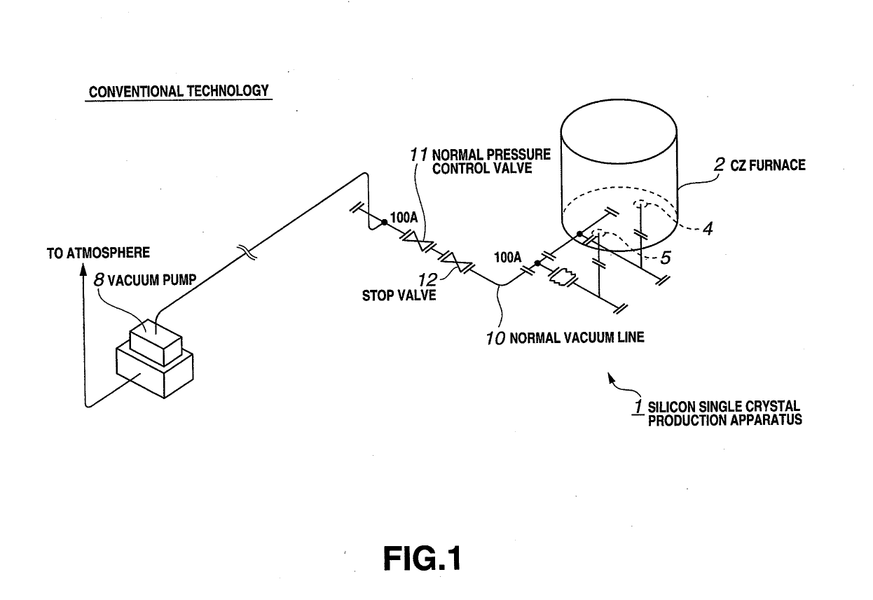

(Effect C) In accordance with the first embodiment, an apparatus suitable for producing both the normal furnace pressure product and the high furnace pressure product can be easily constructed by slightly changing the conventional semiconductor single crystal apparatus 1 (FIG. 1), namely, by newly adding the vacuum line 20 and pressure control valve 21. As a result, the equipment cost can be controlled and the apparatus can be disposed in a limited installation space, without newly adding an additional furnace.

In this case, a high-resistance semiconductor single crystal (normal furnace pressure product) is produced by controlling the normal pressure control valve 11 provided in the normal vacuum line 10 with the controller 40 in the same manner as in the conventional semiconductor single crystal apparatus 1 shown in FIG. 1 and regulating the pressure inside the CZ furnace 2 within the normal furnace pressure region as in the conventional procedure. For the normal furnace pressure product, the pulling conditions such as oxygen concentration are set in the normal furnace pressure region. Therefore, the normal furnace product of high quality can be produced with good yield under pulling conditions that are identical to the conventional pulling conditions.

Some components of the above-described first embodiment can be omitted or changed.

### Second Embodiment

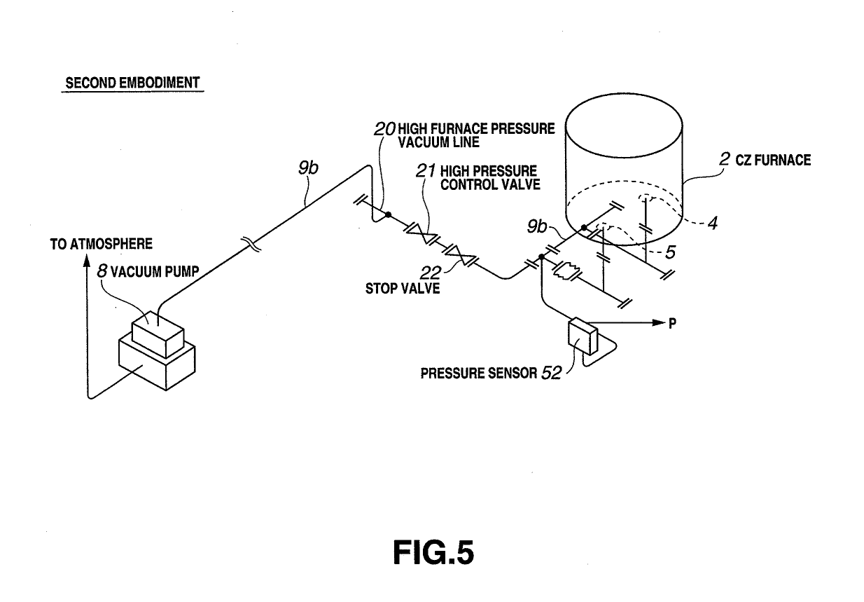

FIG. 5 shows a configuration in which, compared with FIG. 2, normal vacuum line 10 and emergency vacuum line 30 except for the high furnace pressure vacuum line 20 are omitted and only the high furnace pressure vacuum line 20 is provided as a vacuum line linking the CZ furnace 2 to the vacuum pump 8.

With the second embodiment, the above-described effect A can be obtained.

### Third Embodiment

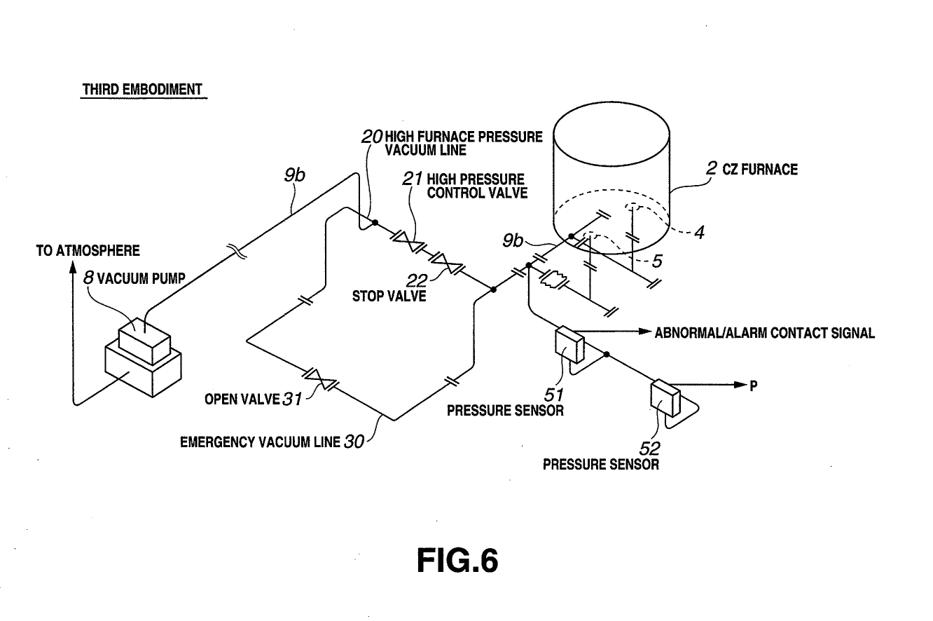

FIG. 6 shows a configuration in which, compared with FIG. 2, normal vacuum line 10 except for the high furnace pressure vacuum line 20 and emergency vacuum line 30 is omitted and only the high furnace pressure vacuum line 20 and emergency vacuum line 30 are provided as vacuum lines linking the CZ furnace 2 to the vacuum pump 8.

With the third embodiment, the above-described effects A and B can be obtained.

### Fourth Embodiment

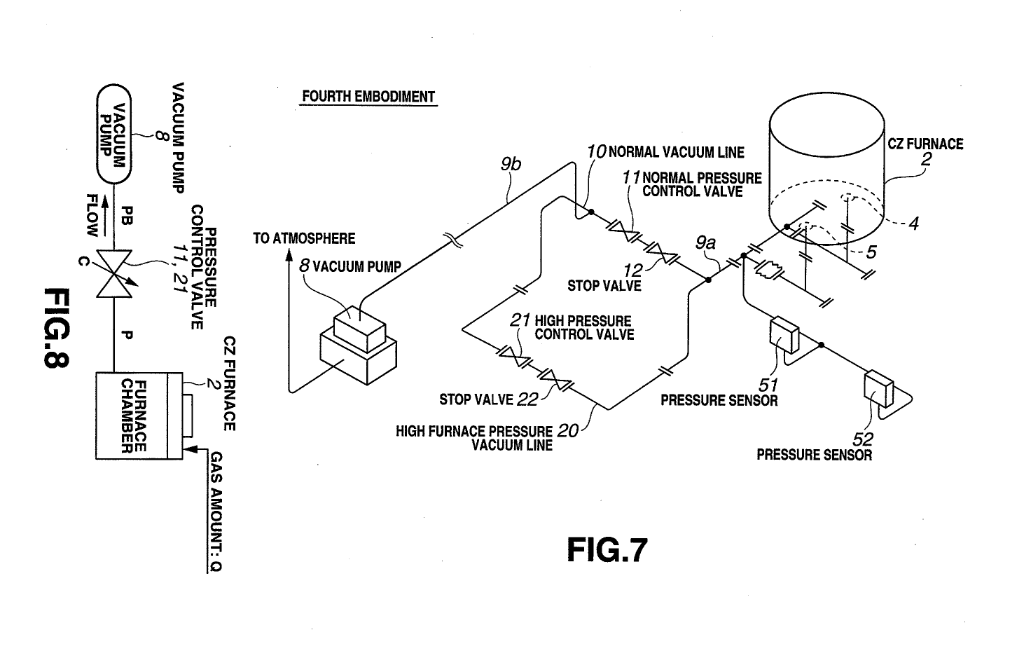

FIG. 7 shows a configuration in which, compared with FIG. 2, emergency vacuum line 30 except for the high furnace pressure vacuum line 20 and normal vacuum line 10 is omitted and only the high furnace pressure vacuum line 20 and normal vacuum line 10 are provided as vacuum lines linking the CZ furnace 2 to the vacuum pump 8.

With the fourth embodiment, the above-described effects A and C can be obtained.

Furthermore, in the fourth embodiment, the emergency opening processing performed in the emergency vacuum line 30 may be performed in the normal vacuum line 10. Thus, in a case where the pressure inside the CZ furnace 2 reaches abnormal value when the high pressure control valve 21 of the high furnace pressure vacuum line 20 is controlled, by opening the pressure control valve 11 of the normal vacuum line 10, the emergency discharge can be carried out and the outflow of gas from inside the CZ furnace 2 to the outside of the furnace can be avoided.

### Fifth Embodiment

In the embodiments described hereinabove, the vacuum region is divided into two regions, two vacuum lines, the high furnace pressure vacuum line 20 and normal vacuum line 10, and two pressure control valves 21, 11 corresponding to these vacuum lines 20, 10 are provided correspondingly to the divided regions, and the pressure of gas flowing in these vacuum lines is regulated. However, the present invention is not limited to the two vacuum regions, two vacuum lines 20, 10, and two pressure control valves 21, 11. Thus, as far as a vacuum line and a pressure control valve which can regulate a pressure within a sub-vacuum region are provided, the vacuum region may be divided into three or more regions, three or more vacuum lines and three or more pressure control valves corresponding to these vacuum lines may be provided correspondingly to the divided regions, and the pressure of gas flowing in these vacuum lines may be regulated.

Furthermore, the embodiments are explained under an assumption that a silicon single crystal is produced as a semiconductor single crystal, but the present invention can be also applied in a similar manner to a case where a semiconductor other than silicon or a compound semiconductor such as gallium arsenide is produced. Furthermore, a CZ method is assumed as a pulling method in the embodiments, but the present invention is not limited to this pulling method. Thus, the present invention obviously can be also applied to a case where a semiconductor single crystal is pulled by a magnetic field application pulling method (MCZ method). Furthermore, the present invention can be also applied to a case where a semiconductor single crystal is pulled by another pulling method that is different from the CZ method (MCZ method), such as a FZ method.

1. A semiconductor single crystal production apparatus in which an inert gas is supplied in a furnace and a semiconductor single crystal doped with a dopant is produced inside the furnace, while discharging the gas in the furnace from an outlet via a vacuum line, comprising:
when a low-resistance semiconductor single crystal doped with a volatile dopant to a high concentration is produced in the furnace,
a high furnace pressure vacuum line and an emergency vacuum line that are provided independently from each other and parallel to each other, are linked to the outlet, and discharge the gas in the furnace;
a pressure control valve that is provided in the high furnace pressure vacuum line, regulates a pressure inside the furnace within a pressure range corresponding to a sub-vacuum region for inhibiting evaporation of a volatile dopant and obtaining a high dopant concentration in the semiconductor single crystal;
an open valve provided in the emergency vacuum line;
pressure detection means for detecting the pressure inside the furnace;
first control means for controlling the pressure control valve based on a detected value of the pressure detection means so as to obtain a desired low resistance value of the semiconductor single crystal; and
second control means for controlling the open valve so as to open the open valve in a case where the pressure inside the furnace detected by the pressure detection means reaches an abnormal value.

2. A semiconductor single crystal production apparatus in which an inert gas is supplied in a furnace and a semiconductor single crystal doped with a dopant is produced inside the furnace, while discharging the gas in the furnace from an outlet via a vacuum line, and
in which a low-resistance semiconductor single crystal doped with a volatile dopant to a high concentration and a semiconductor single crystal with a resistance higher than that of the low-resistance product are produced in the furnace, the semiconductor single crystal production apparatus comprising:
a high furnace pressure vacuum line and a normal vacuum line that are provided independently from each other and parallel to each other, are linked to the outlet, and discharge the gas in the furnace;
a normal pressure control valve that is provided in the normal furnace pressure vacuum line and regulates a pressure inside the furnace within a high-vacuum range;
a high pressure control valve that is provided in the high furnace pressure vacuum line, has an aperture size set smaller than that of the normal pressure control valve, and regulates the pressure inside the furnace within a low-vacuum range; and
control means for controlling the high pressure control valve when the low-resistance semiconductor single crystal is produced and controlling the normal pressure control valve when the high-resistance semiconductor single crystal is produced.

3. A semiconductor single crystal production apparatus in which an inert gas is supplied in a furnace and a semiconductor single crystal doped with a dopant is produced inside the furnace, while discharging the gas in the furnace from an outlet via a vacuum line, and
in which a low-resistance semiconductor single crystal doped with a volatile dopant to a high concentration and a semiconductor single crystal with a resistance higher than that of the low-resistance product are produced in the furnace, the semiconductor single crystal production apparatus comprising:
a high furnace pressure vacuum line, a normal vacuum line, and an emergency vacuum line that are provided independently from each other and parallel to each other, are linked to the outlet, and discharge the gas in the furnace;
a normal pressure control valve that is provided in the normal furnace pressure vacuum line and regulates a pressure inside the furnace within a high-vacuum range;
a high pressure control valve that is provided in the high furnace pressure vacuum line, has an aperture size set smaller than that of the normal pressure control valve, and regulates the pressure inside the furnace within a low-vacuum range;
an open valve provided in the emergency vacuum line;
pressure detection means for detecting the pressure inside the furnace;
first control means for controlling the high pressure control valve when the low-resistance semiconductor single crystal is produced and controlling the normal pressure control valve when the high-resistance semiconductor single crystal is produced; and
second control means for controlling the open valve so as to open the open valve in a case where the pressure inside the furnace detected by the pressure detection means reaches an abnormal value.
